(19) United States
(12) Patent Application Publication
(10) Pub. No.: US 2012/0211764 A1
(43) Pub. Date: Aug. 23, 2012

(54) SEMICONDUCTOR DEVICE AND METHOD FOR MANUFACTURING SEMICONDUCTOR DEVICE

(75) Inventors: Keishiro OKAMOTO, Kawasaki (JP); Tadahiro IMADA, Kawasaki (JP); Nobuhiro IMAIZUMI, Kawasaki (JP); Keiji WATANABE, Kawasaki (JP)

(73) Assignee: FUJITSU LIMITED,, Kawasaki (JP)

(21) Appl. No.: 13/359,855

(22) Filed: Jan. 27, 2012

(30) Foreign Application Priority Data
Feb. 22, 2011 (JP) 2011-036273

(51) Int. Cl. H01L 23/488; H01L 21/60; H01L 29/20

(52) U.S. Cl. 257/76; 257/772; 257/769; 257/770; 257/734; 438/127; 257/E23.023; 257/E29.089; 257/E21.509

(57) ABSTRACT

A semiconductor device includes: a support base material, and a semiconductor element bonded to the support base material with a binder, the binder including: a porous metal material that contacts the support base material and the semiconductor element, and a solder that is filled in at least one part of pores of the porous metal material.

### CROSS-REFERENCE TO RELATED APPLICATION

This application is based upon and claims the benefit of priority of the prior Japanese Patent Application No. 2011-36273, filed on Feb. 22, 2011, the entire contents of which are incorporated herein by reference.

### FIELD

The present invention relates to a semiconductor device and a method for manufacturing the semiconductor device.

### BACKGROUND

In recent years, the development of electronic devices (compound semiconductor devices) in which a GaN layer and an AlGaN layer are sequentially formed on a substrate, and the GaN layer is used as an electron transit layer has been actively performed. As one of such compound semiconductor devices, a GaN-based high electron mobility transistor (HEMT) is mentioned. In the GaN-based HEMT, a high-concentration two-dimensional electron gas (2DEG) formed at a hetero-junction interface of AlGaN and GaN is utilized.

The band gap of GaN is 3.4 eV and is larger than the band gap of Si (1.1 eV) or the band gap of GaAs (1.4 eV). More specifically, GaN has a high breakdown field strength. Moreover, GaN also has a high saturated electron speed. Therefore, GaN is very promising as a material of compound semiconductor devices which allow high-voltage operation and high output. Then, the GaN-based HEMT has been expected as high efficiency switching elements and high breakdown voltage power devices for use in electric vehicles and the like.

In recent years, with respect to not only such GaN-based HEMT but also various semiconductor elements, a reduction in size and a reduction in thickness of semiconductor devices containing semiconductor elements have progressed. In such semiconductor devices, a semiconductor element is bonded onto a lead frame by a solder material or a die bond material, such as a nano Ag paste.

However, it is difficult to obtain sufficient heat dissipation properties with the structure in which the semiconductor element is bonded to the lead frame by the solder material. Moreover, since the junction with the solder material is strong, the thermal stress generated in the junction portion and the vicinity thereof in the operation of the semiconductor element cannot be sufficiently relieved. Therefore, it is hard to say that the junction reliability is good. Moreover, a considerable mechanical stress may work on the semiconductor element in connection with the thermal stress, which may cause malfunction of the semiconductor element. For example, a threshold value voltage of a transistor varies in some cases. Furthermore, when a solder material is melted in order to mount the semiconductor element on the lead frame, a position shift of the semiconductor element is also caused in some cases.

In contrast, in the structure in which the semiconductor element is bonded to the lead frame by the nano Ag paste, stress is relieved and the influence of a position shift of the semiconductor element is smaller than that in the structure in which the semiconductor element is bonded to the lead frame by the solder material. Moreover, high heat dissipation properties can also be obtained. However, it is difficult to secure sufficient junction strength.

In addition to the above, various proposals have been made. However, it has been difficult heretofore to achieve heat dissipation properties, stress relieving properties, and junction strength at the same time.

Japanese Laid-open Patent Publication No. 2001-230351 and Japanese Laid-open Patent Publication No. 2007-201314 are examples of related arts.

### SUMMARY

According to one aspect of the present invention, a semiconductor device includes: a support base material, and a semiconductor element bonded to the support base material with a binder, the binder including: a porous metal material that contacts the support base material and the semiconductor element, and a solder that is filled in at least one part of pores of the porous metal material.

The object and advantages of the invention will be realized and attained by means of the elements and combinations particularly pointed out in the claims. It is to be understood that both the foregoing general description and the following detailed description are exemplary and explaneatory and are not restrictive of the invention, as claimed.

### BRIEF DESCRIPTION OF DRAWINGS

FIGS. 1A and 1B are views illustrating the structure of a semiconductor device according to a first embodiment;

FIGS. 2A to 2G are cross sectional views illustrating a method for manufacturing the semiconductor device according to the first embodiment in the order of processes;

FIG. 3 is a view illustrating one aspect of a semiconductor element;

FIG. 4 is a view illustrating the structure of a semiconductor device according to a second embodiment;

FIGS. 5A to 5F are cross sectional views illustrating the method for manufacturing the semiconductor device according to the second embodiment in the order of processes;

FIG. 6 is a view illustrating the structure of a semiconductor device according to a third embodiment;

FIGS. 7A to 7G are cross sectional views illustrating a method for manufacturing the semiconductor device according to the third embodiment in the order of processes;

FIG. 8 is a view illustrating the structure of a semiconductor device according to a fourth embodiment;

FIGS. 9A to 9H are cross sectional views illustrating a method for manufacturing the semiconductor device according to the fourth embodiment in the order of processes;

FIG. 10 is a view illustrating the structure of a semiconductor device according to a fifth embodiment;

FIGS. 11A to 11G are cross sectional views illustrating a method for manufacturing the semiconductor device according to the fifth embodiment in the order of processes;

FIG. 12 is a view illustrating the structure of a semiconductor device according to a sixth embodiment;

FIGS. 13A to 13F are cross sectional views illustrating the method for manufacturing the semiconductor device according to the sixth embodiment in the order of processes;

FIG. 14 is a view illustrating the structure of a semiconductor device according to a seventh embodiment;

FIGS. 15A to 15G are cross sectional views illustrating the method for manufacturing the semiconductor device according to the seventh embodiment in the order of processes;

FIG. 16 is a view illustrating a discrete package containing a GaN- based HEMT; and

FIGS. 17A to 17B is a view illustrating a power supply device.

### DESCRIPTION OF EMBODIMENTS

Hereinafter, the embodiments are specifically described with reference to the attached drawings.

### First Embodiment

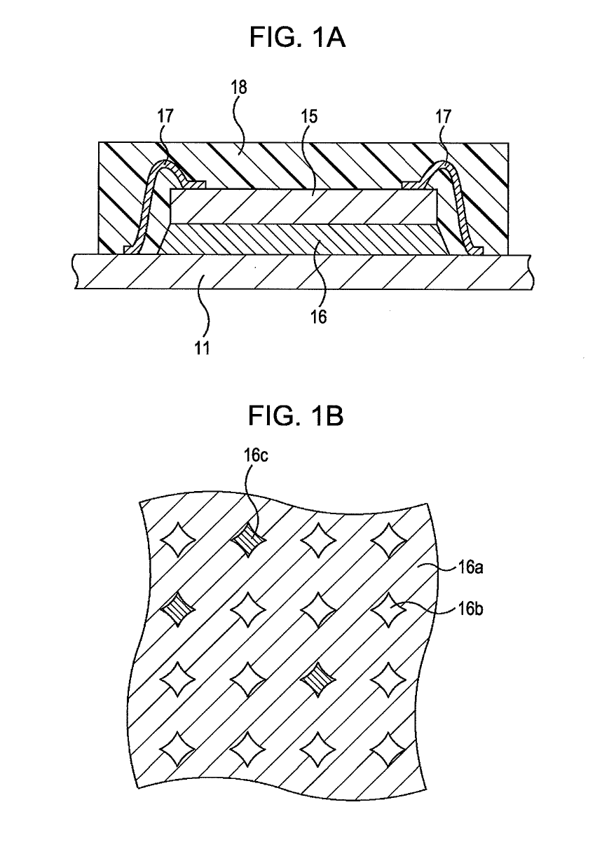

First, a first embodiment is described. FIG. 1 is a view illustrating the structure of a semiconductor device according to a first embodiment.

In the first embodiment, a semiconductor element 15 is bonded to a lead frame 11 through a composite material 16 as illustrated in FIG. 1A. The composite material 16 is one example of binders. The semiconductor element 15 is provided with terminals, and the terminals are connected to the leads of the lead frame 11 through bonding wires 17. The semiconductor element 15, the composite material 16, and the bonding wires 17 are sealed with a mold resin 18.

In the first embodiment, the composite material 16 contains a film-like porous metal material 16a as illustrated in FIG. 1B. One principal surface of the porous metal material 16a contacts the semiconductor element 15 and the other principal surface contacts the lead frame 11. At least one part, e.g., the entire, of pores 16b of the porous metal material 16a is filled with a solder 16c. In FIG. 1B, the pores 16b are regularly arranged, but the pores 16b do not need to be regularly arranged.

In the first embodiment, the heat generated in the semiconductor element 15 can be sufficiently transmitted to the lead frame 11 through the porous metal material 16a contained in the composite material 16. Even when stress is generated with the generation of heat, the stress is relieved by the porous metal material 16a. Furthermore, since at least one part of the pores 16b of the porous metal material 16a is filled with the solder 16c, it is also possible to secure sufficient junction strength between the lead frame 11 and the semiconductor element 15.

Since the stress can be sufficiently relieved, even when a transistor, such as a GaN-based HEMT transistor, is contained in the semiconductor element, a variation in the threshold value voltage thereof can be suppressed. For example, even when a high temperature storage test and a temperature cycle test are performed, damages to the semiconductor element 15 can be remarkably reduced.

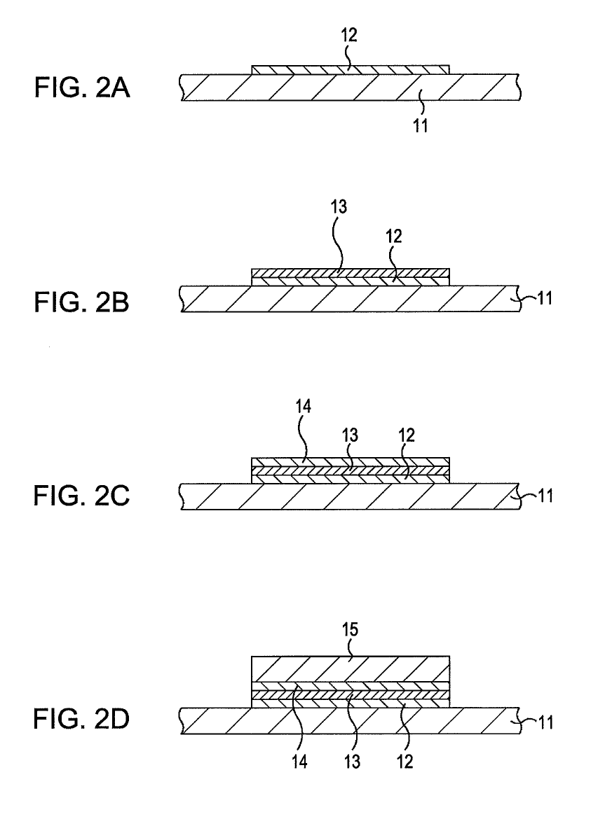

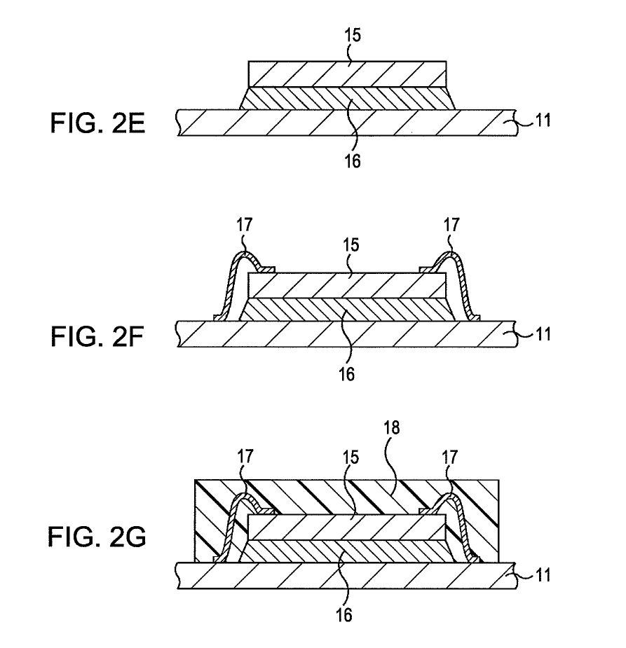

Next, a method for manufacturing the semiconductor device according to the first embodiment is described. FIGS. 2A to 2G are cross sectional views illustrating the method for manufacturing the semiconductor device according to the first embodiment in the order of processes.

First, as illustrated in FIG. 2A, a nano Ag paste 12 is applied to a region of the lead frame 11 where the semiconductor element 15 is to be mounted. The nano Ag paste 12 is a paste containing Ag particles having a particle size of 1 μm or lower, for example. A paste containing Ag particles having a particle size of 100 nm or lower may be used and a paste containing Ag particles having a particle size of 10 nm or lower may be used. The application method of the nano Ag paste 12 is not particularly limited. The nano Ag paste 12 can be applied by a dispense method, a printing method, a transfer method, or the like.

Subsequently, as illustrated in FIG. 2B, a solder sheet 13 is formed on the nano Ag paste 12.

Thereafter, as illustrated in FIG. 2C, a nano Ag paste 14 is applied onto the solder sheet 13. The nano Ag paste 14 is also a paste containing Ag particles having a particle size of 1 μm or lower, for example. A paste containing Ag particles having a particle size of 100 nm or lower may be used and a paste containing Ag particles having a particle size of 10 nm or lower may be used. The application method of the nano Ag paste 14 is not particularly limited. The nano Ag paste 14 can be applied by a dispense method, a printing method, a transfer method, or the like.

As the solder sheet 13, materials are not particularly limited insofar as the materials have a melting point which is higher than the temperature at which the Ag particles contained in the nano Ag pastes 12 and 14 are sintered and a melting point which is lower than the melting point of the Ag particles. For example, a SnAgCu-based solder sheet can be used.

Subsequently, as illustrated in FIG. 2D, the semiconductor element 15 is mounted in a face-up manner on the nano Ag paste 14. The type of the semiconductor element 15 is not particularly limited and, for example, a GaN-based HEMT or the like can be used.

Then, at least the nano Ag paste 12, the solder sheet 13, and the nano Ag paste 14 are heated to melt the solder sheet 13. Thereafter, the molten solder is solidified by cooling. In this process, since the melting point of the solder sheet 13 is higher than the temperature at which the Ag particles contained in the nano Ag pastes 12 and 14 are sintered, the Ag particles contained in the nano Ag pastes 12 and 14 are sintered before the solder sheet 13 melts, to thereby form a film-like porous metal material 16a. When the solder sheet 13 melts, the molten solder flows into the pores 16b of the porous metal material 16a. When the solder is solidified with the subsequent cooling process, the composite material 16 is formed which contains the porous metal material 16a and the solder charged in at least one part of the pores 16b as illustrated in FIG. 2E. One principal surface of the porous metal material 16a contacts the semiconductor element 15 and the other principal surface thereof contacts the lead frame 11. The heating method is not particularly limited, and the heating temperature and the heating time are not particularly limited insofar as the solder sheet 13 melts. For example, heating may be performed at 240° C. for 10 minutes with a conveyor type reflow furnace.

Thereafter, as illustrated in FIG. 2F, the terminals of the semiconductor element 15 are connected to the leads of the lead frame 11 by die bonding using the bonding wires 17. As the bonding wires 17, Al wire is used, for example. When the semiconductor element 15 is a GaN-based HEMT, a gate terminal of the semiconductor element 15 is connected to a gate lead of the lead frame 11, a source terminal of the semiconductor element 15 is connected to a source lead of the lead frame 11, and a drain terminal of the semiconductor element 15 is connected to a drain lead of the lead frame 11, for example.

Subsequently, as illustrated in FIG. 2G, the semiconductor element 15, the composite material 16, and the bonding wires 17 are sealed with the mold resin 18. For example, an assembly containing the semiconductor element 15, the composite material 16, and the bonding wires 17 is placed in a die of a resin sealing (mold) device, and is sealed with a thermosetting sealing resin.

Thereafter, the resin-sealed assembly is removed from the die, and then the outer leads of the lead frame 11 are cut to divide the same into semiconductor devices. Thus, a discrete package containing the GaN-based HEMT semiconductor element 15, for example, is obtained.

According to such a method, there is no necessity of using expensive materials as compared with former cases. Therefore, a semiconductor device which can achieve heat dissipation properties, stress relieving properties, and junction strength can be obtained while suppressing an increase in cost.

The materials of the porous metal material 16a are not particularly limited. For example, a substance (a metal simple substance, an alloy, or a mixture) containing at least one selected from the group consisting of Ag, Au, Ni, Cu, Pt, Pd, and Sn can be used. The same substance is applied to the following embodiments.

Moreover, the material of the solder sheet 13 is not particularly limited insofar as the melting point thereof is higher than the temperature at which the material of the porous metal material 16a is sintered. For example, a substance (a metal simple substance, an alloy, or a mixture) containing at least one selected from the group consisting of Sn, Ni, Cu, Zn, Al, Bi, Ag, In, Sb, Ga, Au, Si, Ge, Co, W, Ta, Ti, Pt, Mg, Mn, Mo, Cr, and P can be used. The same substance is applied to the following embodiments.

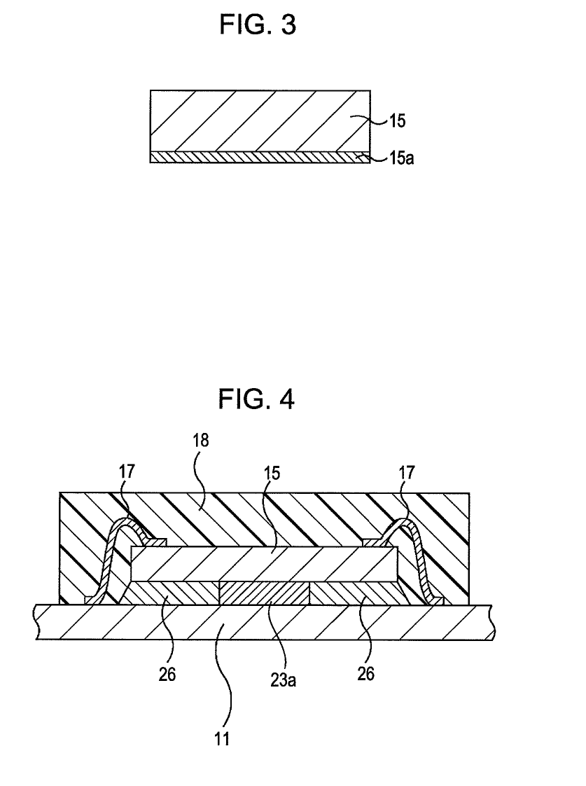

It is preferable that a metal film 15a is formed on the rear surface of the semiconductor element 15 as illustrated in FIG. 3. It is because the wettability of the solder of the solder sheet 13 is increased by the metal film 15a, so that more secure junction can be achieved and the thermal conductivity with the porous metal material 16a is increased. The metal film 15a can be formed by a sputtering method, a vapor deposition method, a plating method, or the like. For example, a Ti film, a Pt film, and an Au film are formed in this order. The material of the metal film 15a is not particularly limited and, for example, a substance (a metal simple substance, an alloy, or a mixture) containing at least one selected from the group consisting of Ni, Cu, Zn, Al, Ag, Au, W, Ti, Pt, and Cr can be used. The same substance is applied to the following embodiments.

According to the semiconductor device and the like described above, good heat dissipation properties and stress relieving properties can be obtained by the porous metal material, and good junction strength can be obtained by the solder.

### Second Embodiment

Next, a second embodiment is described. FIG. 4 is a view illustrating the structure of a semiconductor device according to a second embodiment.

In the second embodiment, the semiconductor element 15 is bonded to the lead frame 11 through a composite material 26 and a solder layer 23a as illustrated in FIG. 4. The composite material 26 and the solder layer 23a each are one example of binders. More specifically, at least one part of the semiconductor element 15 contacts the composite material 26 and at least another part of the semiconductor element 15 contacts the solder layer 23a. For example, the outer region of the semiconductor element 15 contacts the composite material 26 and the inner region thereof contacts the solder layer 23a. The composite material 26 contains a porous metal material similarly as in the composite material 16, and at least one part of the pores of the porous metal material is charged with a solder. The other configurations are the same as those of the first embodiment.

According to the second embodiment, higher junction strength can be obtained as compared with the first embodiment. In particular, when the outer region of the semiconductor element 15 contacts the composite materials 26 and the inner region contacts the solder layer 23a, high junction strength can be obtained at the central portion on which stress hardly acts while effectively relieving the stress at the outer region on which relatively high stress acts.

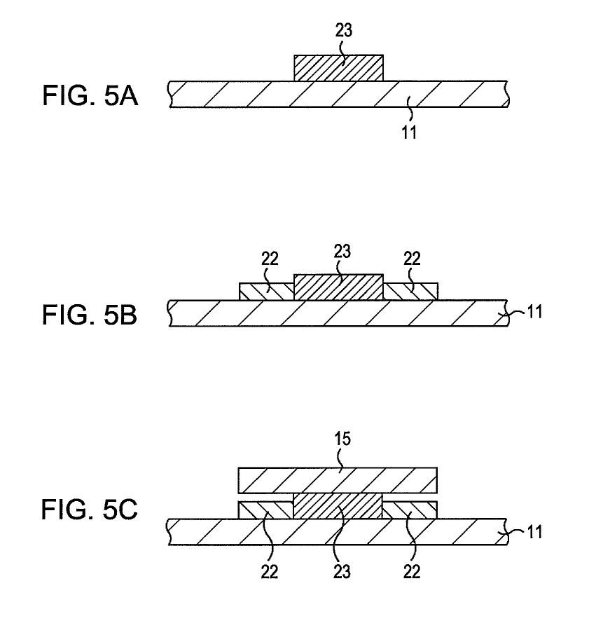

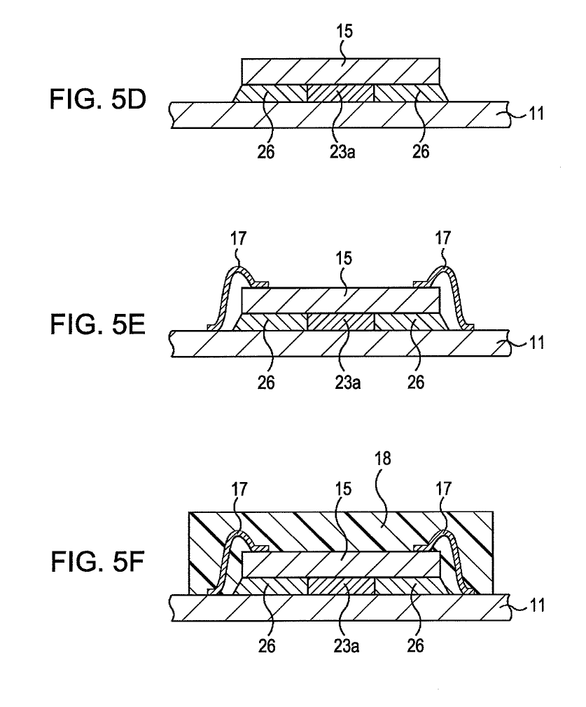

Next, a method for manufacturing the semiconductor device according to the second embodiment is described. FIGS. 5A to 5F are cross sectional views illustrating the method for manufacturing the semiconductor device according to the second embodiment in the order of processes.

First, as illustrated in FIG. 5A, the solder sheet 23 is disposed at the central portion of a region of the lead frame 11 where the semiconductor element 15 is to be mounted. As the material of the solder sheet 23, the same material as in the solder sheet 13 may be used.

Subsequently, a nano Ag paste 22 is applied to the circumference of the solder sheet 23 in a region of the lead frame 11 where the semiconductor element 15 is to be mounted as illustrated in FIG. 5B. As the nano Ag paste 22, the same one as in the nano Ag pastes 12 and 14 may be used.

Thereafter, the semiconductor element 15 is mounted in a face-up manner on the solder sheet 23 and the nano Ag paste 22 as illustrated in FIG. 5C.

Subsequently, at least the nano Ag paste 22 and the solder sheet 23 are heated to mold the solder sheet 23. Thereafter, the molten solder is solidified by cooling. In this process, the Ag particles contained in the nano Ag paste 22 are sintered before the solder sheet 23 melts, to thereby form a film-like porous metal material. Then, when the solder sheet 23 melts, the molten solder partially flows into the pores of the porous metal material, and the remaining molten solder remains at the central portion. When the solder is solidified with the subsequent cooling process, the composite material 26 is formed and the solder layer 23a is formed inside the composite material 26 as illustrated in FIG. 5D.

Thereafter, as illustrated in FIG. 5E, the terminals of the semiconductor element 15 are connected to the leads of the lead frame 11 by die bonding using the bonding wires 17. Subsequently, as illustrated in FIG. 5F, the semiconductor element 15, the composite materials 26, the solder layer 23a, and the bonding wires 17 are sealed with the mold resin 18.

Thereafter, a resin-sealed assembly is removed from a die, and then the outer leads of the lead frame 11 are cut to divide the same into semiconductor devices. Thus, a discrete package containing the GaN-based HEMT semiconductor element 15, for example, is obtained.

### Third Embodiment

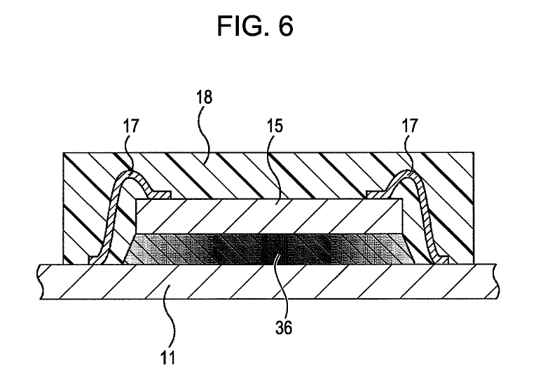

Next, a third embodiment is described. FIG. 6 is a view illustrating the structure of a semiconductor device according to the third embodiment.

In the third embodiment, as illustrated in FIG. 6, the semiconductor element 15 is bonded to the lead frame 11 through a composite material 36. The composite material 36 is one example of binders. The composite material 36 contains a porous metal material, and at least one part of the pores of the porous metal material is filled with a solder. However, unlike the composite material 16, the solder ratio decreases and the porous metal material ratio becomes higher from the central portion to the outer region. The other configurations are the same as those of the first embodiment.

According to the third embodiment, high junction strength can be obtained at the central portion on which stress hardly acts while effectively relieving stress at the outer region on which relatively high stress acts.

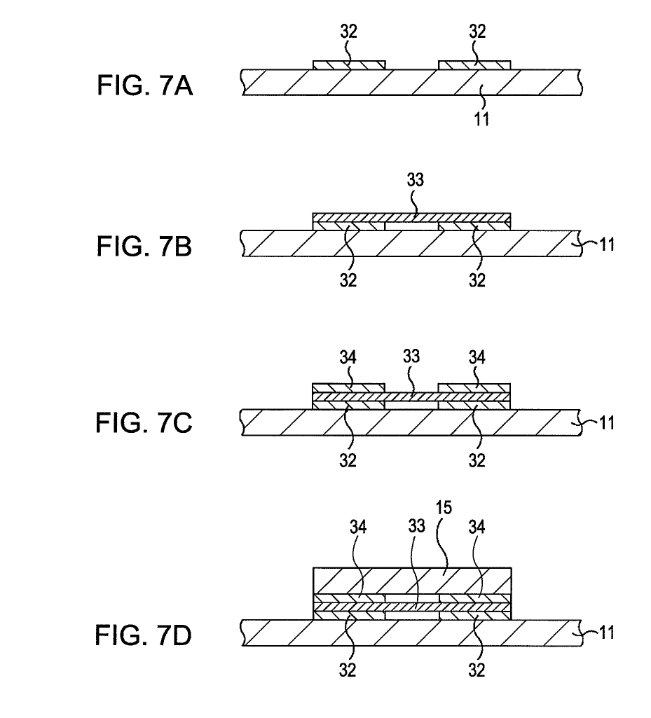

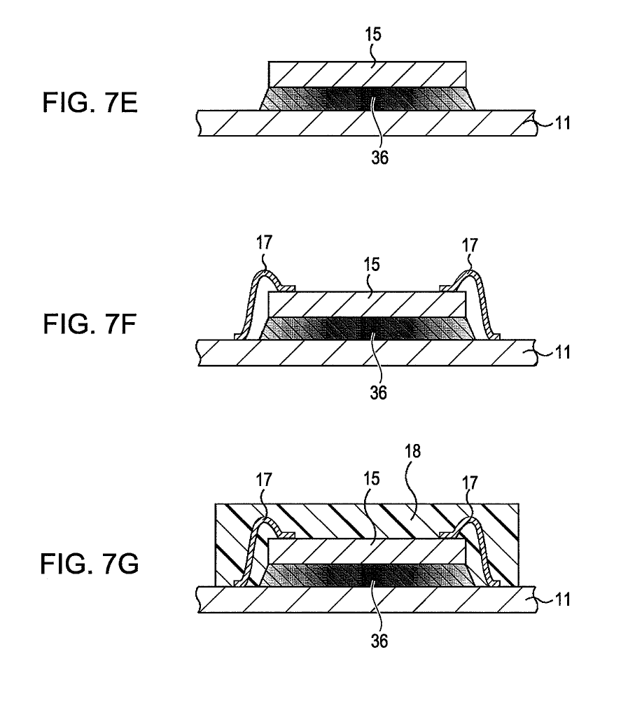

Next, a method for manufacturing the semiconductor device according to the third embodiment is described. FIGS. 7A to 7G are cross sectional views illustrating the method for manufacturing the semiconductor device according to the third embodiment in the order of processes.

First, as illustrated in FIG. 7A, a nano Ag paste 32 is applied to the outer region of a region of the lead frame 11 where the semiconductor element 15 is to be mounted. As the nano Ag paste 32, the same one as in the nano Ag pastes 12 and 14 may be used.

Subsequently, as illustrated in FIG. 7B, a solder sheet 33 is formed on the nano Ag paste 32 having an annular shape in such a manner as to also cover an opening portion inside the nano Ag paste 32. As the solder sheet 33, the same one as in the solder sheet 13 may be used.

Thereafter, as illustrated in FIG. 7C, a nano Ag paste 34 is applied to the outer region of the solder sheet 33. As the nano Ag paste 34, the same one as in the nano Ag pastes 12 and 14 may be used.

Subsequently, as illustrated in FIG. 7D, the semiconductor element 15 is mounted in a face-up manner on the nano Ag pastes 34.

Then, at least the nano Ag paste 32, the solder sheet 33, and the nano Ag paste 34 are heated to solidify the solder sheet 33. Thereafter, the molten solder is solidified by cooling. In this process, the Ag particles contained in the nano Ag pastes 32 and 34 before the solder sheet 33 melts, to thereby form a film-like porous metal material. Then, when the solder sheet 33 melts, the molten solder flows into the pores of the porous metal material. When the solder is solidified with the subsequent cooling process, the composite material 36 is formed so that the solder ratio decreases from the central portion to the outer region as illustrated in FIG. 7E.

Thereafter, as illustrated in FIG. 7F, the terminals of the semiconductor element 15 are connected to the leads of the lead frame 11 by die bonding using the bonding wires 17. Subsequently, as illustrated in FIG. 7G, the semiconductor element 15, the composite material 36, and the bonding wires 17 are sealed with the mold resin 18.

Thereafter, a resin-sealed assembly is removed from a die, and then the outer leads of the lead frame 11 are cut to divide the same into semiconductor devices. Thus, a discrete package containing the GaN-based HEMT semiconductor element 15, for example, is obtained.

### Fourth Embodiment

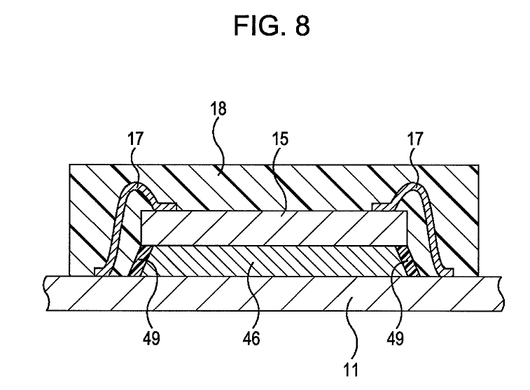

Next, a fourth embodiment is described. FIG. 8 is a view illustrating the structure of a semiconductor device according to a fourth embodiment.

As illustrated in FIG. 8, in the fourth embodiment, a resin material 49 is interposed between the semiconductor element 15 and the lead frame 11 at the outer region of the semiconductor element 15 and the semiconductor element 15 is bonded to the lead frame 11 inside the resin material 49 through a composite material 46. More specifically, the central portion of the semiconductor element 15 contacts the composite material 26 and the outer region of the semiconductor element 15 contacts the resin material 49. The composite material 46 is one example of binders. The composite material 46 contains a porous metal material similarly as in the composite material 16, and at least one part of the pores of the porous metal material is charged with a solder. The other configurations are the same as those of the first embodiment.

According to the fourth embodiment, at the outer region on which relatively high stress acts, the stress can be effectively relieved by the resin material 49.

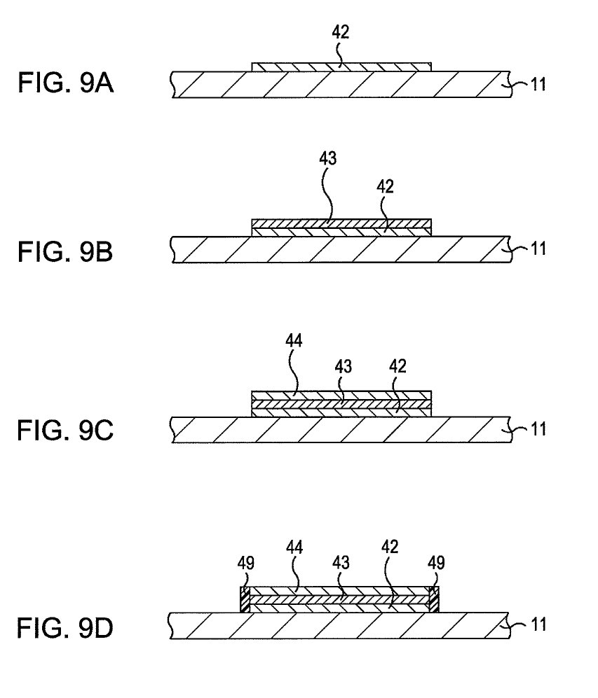

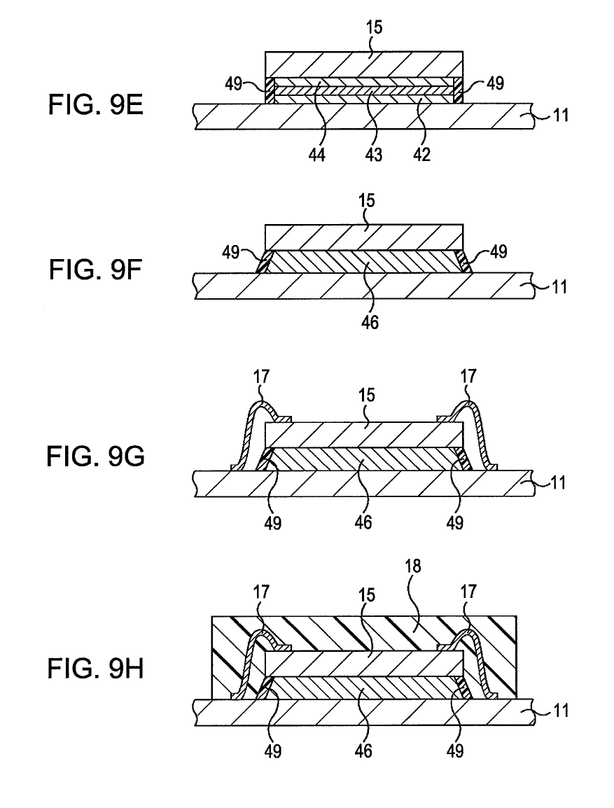

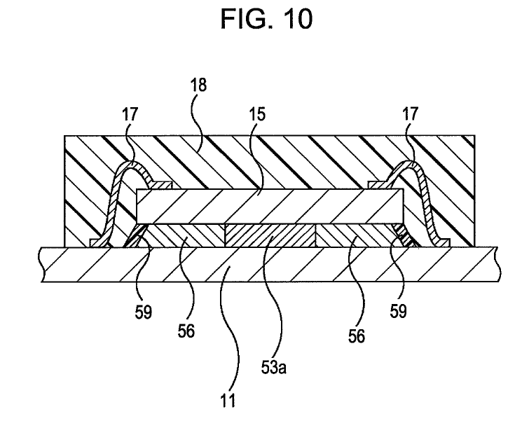

Next, a method for manufacturing the semiconductor device according to the third embodiment is described. FIGS. 9A to 9H are cross sectional views illustrating the method for manufacturing the semiconductor device according to the fourth embodiment in the order of processes.

First, as illustrated in FIG. 9A, a nano Ag paste 42 is applied to the central portion of a region of the lead frame 11 where the semiconductor element 15 is to be mounted. As the nano Ag paste 42, the same one as in the nano Ag pastes 12 and 14 may be used.

Subsequently, as illustrated in FIG. 9B, a solder sheet 43 is disposed on the nano Ag paste 42. As the solder sheet 43, the same one as in the solder sheet 13 may be used.

Thereafter, as illustrated in FIG. 9C, a nano Ag paste 44 is applied onto the solder sheet 43. As the nano Ag paste 44, the same one as in the nano Ag pastes 12 and 14 may be used.

Subsequently, as illustrated in FIG. 9D, a resin material 49 is provided at the circumference of a laminate of the nano Ag paste 42, the solder sheet 43, and the nano Ag paste 44. As the resin material 49, a resin paste can be used, for example.

Subsequently, as illustrated in FIG. 9E, the semiconductor element 15 is mounted in a face-up manner on the nano Ag paste 44 and the resin material 49.

Thereafter, at least the nano Ag paste 42, the solder sheet 43, and the nano Ag paste 44 are heated to molt the solder sheet 43. Thereafter, the molten solder is solidified by cooling. In this process, the Ag particles contained in the nano Ag pastes 42 and 44 are sintered before the solder sheet 43 melts, to thereby form a film-like porous metal material. Then, when the solder sheet 43 melts, the molten solder flows into the pores of the porous metal material. When the solder is solidified with the subsequent cooling process, the composite material 46 is formed which contains the porous metal material and the solder charged in at least one part of the pores as illustrated in FIG. 9F. Moreover, the side surfaces of the composite material 46 are covered with the resin material 49. More specifically, the resin material 49 remains in a state where the resin material 49 contacts the undersurface of the semiconductor element 15 and the upper surface of the lead frame 11.

Subsequently, as illustrated in FIG. 9G, the terminals of the semiconductor element 15 are connected to the leads of the lead frame 11 by die bonding using the bonding wires 17. Then, as illustrated in FIG. 9H, the semiconductor element 15, the composite material 46, the resin material 49, and the bonding wires 17 are sealed with the mold resin 18.

Thereafter, a resin-sealed assembly is removed from a die, and then the outer leads of the lead frame 11 are cut to divide the same into semiconductor devices. Thus, a discrete package containing the GaN-based HEMT semiconductor element 15, for example, is obtained.

### Fifth Embodiment

Next, a fifth embodiment is described. FIG. 10 is a view illustrating the structure of a semiconductor device according to a fifth embodiment.

In the fifth embodiment, a resin material 59 is interposed between the semiconductor element 15 and the lead frame 11 at the outer region of the semiconductor element 15 and the semiconductor element 15 is bonded to the lead frame 11 inside the resin material 59 through a composite material 56 and a solder layer 53a as illustrated in FIG. 10. More specifically, at least one part of the central portion of the semiconductor element 15 contacts the composite material 56, at least another portion of the central portion of the semiconductor element 15 contacts the solder layer 53a, and the outer region of the semiconductor element 15 contacts the resin material 59. For example, at the central portion of the semiconductor element 15, the solder layer 53a is located inside the composite material 56. The composite material 56 and the solder layer 53a each are one example of binders. The composite material 56 contains a porous metal material similarly as in the composite material 16, and at least one part of the pores of the porous metal material is charged with a solder. The other configurations are the same as those of the first embodiment.

According to the fifth embodiment, the effects of the second embodiment and the fourth embodiment can be obtained. More specifically, higher junction strength can be obtained at the central portion on which stress hardly acts as compared with the fourth embodiment.

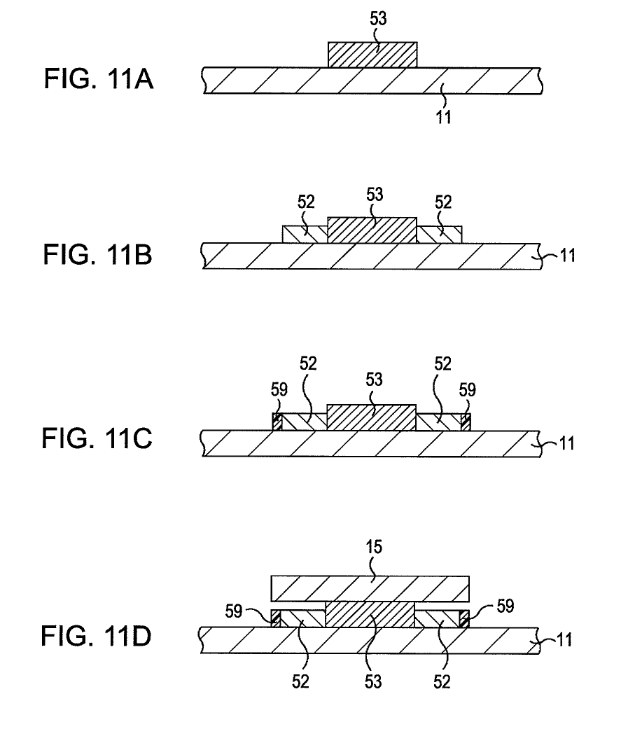

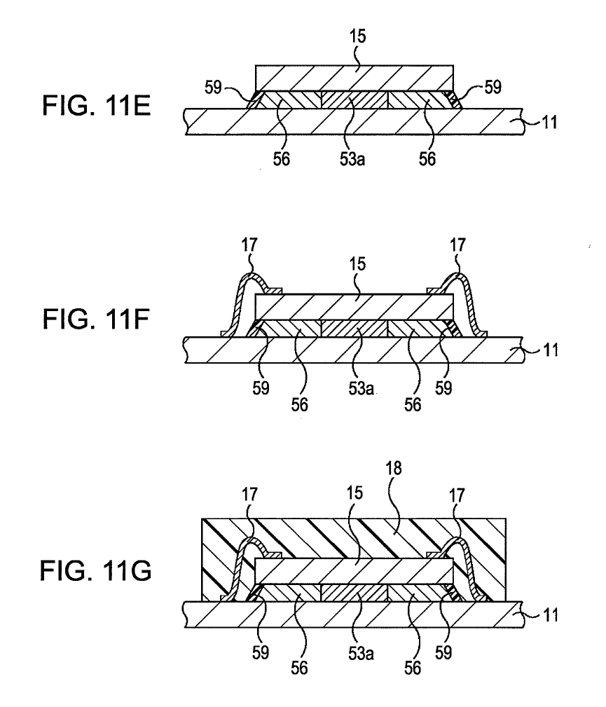

Next, a method for manufacturing the semiconductor device according to the fifth embodiment is described. FIGS. 11A to 11G cross sectional views illustrating the method for manufacturing the semiconductor device according to the fifth embodiment in the order of processes.

First, as illustrated in FIG. 11A, a solder sheet 53 is disposed at the central portion of a region of the lead frame 11 where the semiconductor element 15 is to be mounted. As the material of the solder sheet 53, the same one as in the solder sheet 13 may be used.

Subsequently, as illustrated in FIG. 11B, a nano Ag paste 52 is applied to the circumference of the solder sheet 53 in the region of the lead frame 11 where the semiconductor element 15 is to be mounted. As the nano Ag paste 52, the same one as in the nano Ag pastes 12 and 14 may be used.

Thereafter, as illustrated in FIG. 11C, a resin material 59 is provided at the circumference of the nano Ag paste 52. As the resin material 59, a resin paste can be used, for example.

Then, as illustrated in FIG. 11D, the semiconductor element 15 is mounted in a face-up manner on the solder sheet 53, the nano Ag paste 52, and the resin material 59.

Subsequently, at least the nano Ag paste 52 and the solder sheet 53 are heated to molt the solder sheet 53. Thereafter, the molten solder is solidified by cooling. In this process, the Ag particles contained in the nano Ag paste 52 are sintered before the solder sheet 53 melts, to thereby form a film- like porous metal material. Then, when the solder sheet 53 melts, the molten solder partially flows into the pores of the porous metal material and the remaining molten solder remains at the central portion. When the solder is solidified with the subsequent cooling process, the composite material 56 is formed as illustrated in FIG. 11E, and a solder sheet 53a is formed inside the composite material 56. The side surfaces of the composite material 56 are covered with the resin material 59. More specifically, the resin material 59 remains in a state where the resin material 59 contacts the undersurface of the semiconductor element 15 and the upper surface of the lead frame 11.

Thereafter, as illustrated in FIG. 11F, the terminals of the semiconductor element 15 are connected to the leads of the lead frame 11 by die bonding using the bonding wires 17. Subsequently, as illustrated in FIG. 11G, the semiconductor element 15, the composite material 56, the resin material 59, and the bonding wires 17 are sealed with the mold resin 18.

Thereafter, a resin-sealed assembly is removed from a die, and then the outer leads of the lead frame 11 are cut to divide the same into semiconductor devices. Thus, a discrete package containing the GaN-based HEMT semiconductor element 15, for example, is obtained.

### Sixth Embodiment

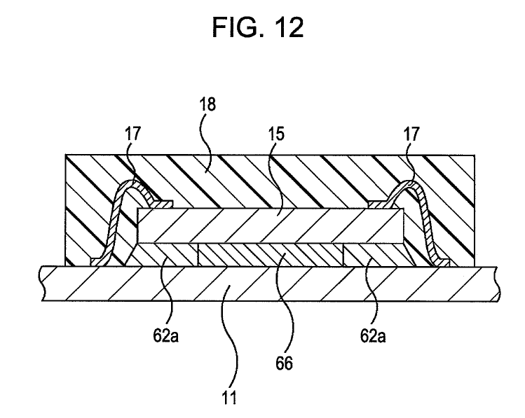

Next, a sixth embodiment is described. FIG. 12 is a view illustrating the structure of a semiconductor device according to the sixth embodiment.

In the sixth embodiment, the semiconductor element 15 is bonded to the lead frame 11 through a composite material 66 and a porous metal material 62a not containing a solder as illustrated in FIG. 12. More specifically, at least one part of the semiconductor element 15 contacts the composite material 66 and at least another part of the semiconductor element 15 contacts the porous metal material 62a. For example, the outer region of the semiconductor element 15 contacts the porous metal material 62a and the inner region thereof contacts the composite material 66. The composite material 66 and the porous metal material 62a each are one example of binders. The composite material 66 contains a porous metal material similarly as in the composite material 16, and at least one part of the pores of the porous metal material is charged with a solder. The other configurations are the same as those of the first embodiment.

According to the sixth embodiment, at the outer region on which relatively high stress acts, the stress can be more effectively relieved.

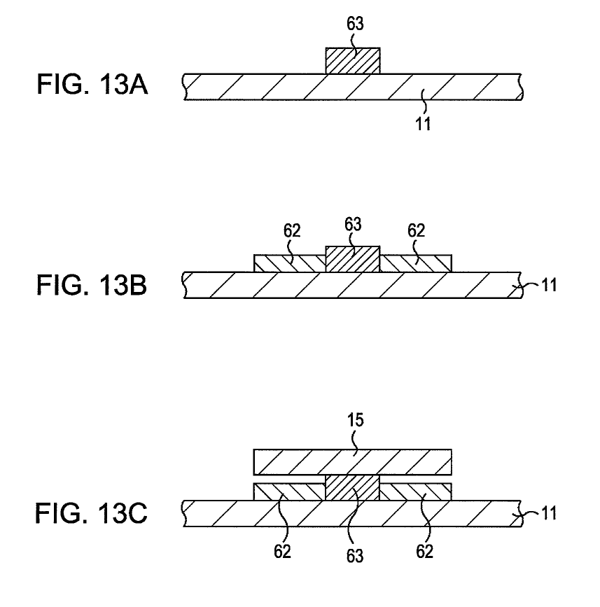

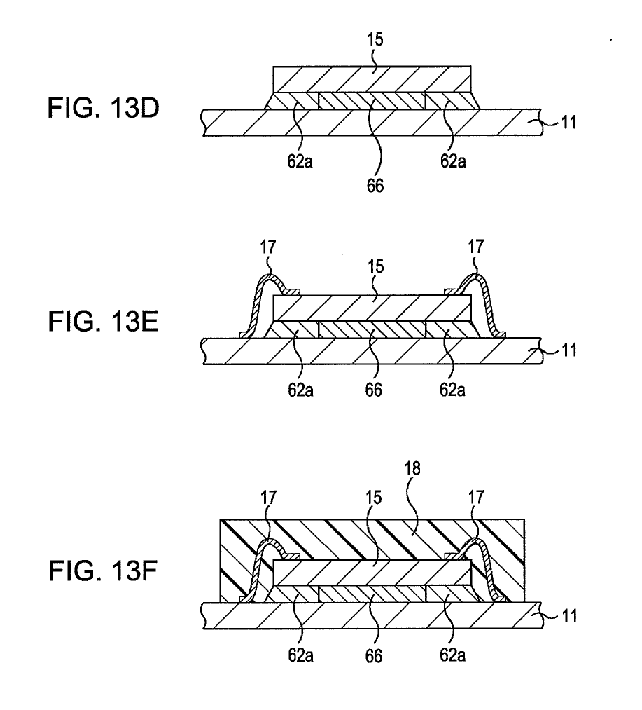

Next, a method for manufacturing the semiconductor device according to the sixth embodiment is described. FIGS. 13A to 13F are cross sectional views illustrating the method for manufacturing the semiconductor device according to the sixth embodiment in the order of processes.

First, as illustrated in FIG. 13A, a solder sheet 63 is disposed at the central portion of a region of the lead frame 11 where the semiconductor element 15 is to be mounted. As the material of the solder sheet 63, the same one as in the solder sheet 13 may be used. As the solder sheet 63, one smaller than the solder sheet 23 of the second embodiment is used.

Subsequently, as illustrated in FIG. 13B, a nano Ag paste 62 is applied to the circumference of the solder sheet 63 in the region of the lead frame 11 where the semiconductor element 15 is to be mounted. As the nano Ag paste 52, the same one as in the nano Ag pastes 12 and 14 may be used. The nano Ag paste 62 is applied to a wider area than the area of the nano Ag paste 22 of the second embodiment corresponding to the size of the solder sheet 63 which is smaller than the solder sheet 23.

Thereafter, as illustrated in FIG. 13C, the semiconductor element 15 is mounted in a face-up manner on the solder sheet 63 and the nano Ag paste 62.

Subsequently, at least the nano Ag paste 62 and the solder sheet 63 are heated to molt the solder sheet 63. Thereafter, the molten solder is solidified by cooling. In this process, the Ag particles contained in the nano Ag paste 62 are sintered before the solder sheet 63 melts, to thereby form a film- like porous metal material. Then, when the solder sheet 63 melts, the molten solder partially flows into the pores of the porous metal material. In this case, the amount of the solder sheet 63 is small in the sixth embodiment, and therefore, the entire solder flows into the pores of the porous metal material. In contrast, the solder does not flow into the outer region of the porous metal material. When the solder is solidified with the subsequent cooling process, a porous metal material 62a is formed at the outer region and a composite material 66 is formed inside the porous metal material.

Subsequently, as illustrated in FIG. 13E, the terminals of the semiconductor element 15 are connected to the leads of the lead frame 11 by die bonding using the bonding wires 17. Subsequently, as illustrated in FIG. 13F, the semiconductor element 15, the composite material 66, the porous metal material 62a, and the bonding wires 17 are sealed with the mold resin 18.

Thereafter, a resin-sealed assembly is removed from a die, and then the outer leads of the lead frame 11 are cut to divide the same into semiconductor devices. Thus, a discrete package containing the GaN-based HEMT semiconductor element 15, for example, is obtained.

### Seventh Embodiment

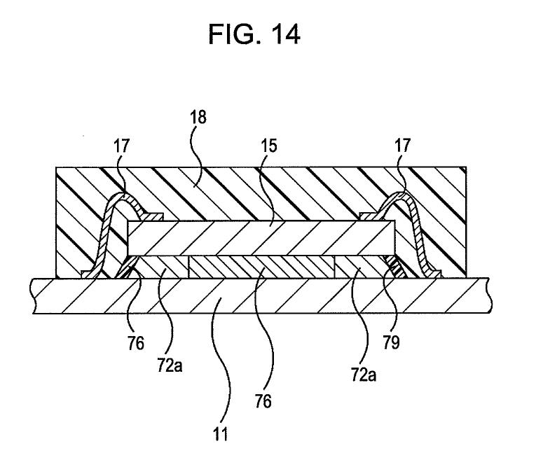

Next, a seventh embodiment is described. FIG. 14 is a view illustrating the structure of a semiconductor device according to the seventh embodiment.

In the seventh embodiment, as illustrated in FIG. 14, a resin material 79 is interposed between the semiconductor element 15 and the lead frame 11 at the outer region of the semiconductor element 15 and the semiconductor element 15 is bonded to the lead frame 11 inside the resin material 79 through a composite material 76 and a porous metal material 72a not containing a. solder. More specifically, at least one part of the central portion the semiconductor element 15 contacts the composite material 76, at least another part of the central portion of the semiconductor element 15 contacts the porous metal material 72a, and the outer region of the semiconductor element 15 contacts a resin material 79. For example, at the central portion of the semiconductor element 15, the composite material 76 is disposed inside the porous metal material 72a. The composite material 76 and the porous metal material 72a each are one example of binders. The composite material 76 contains a porous metal material similarly as in the composite material 16, and at least one part of the pores of the porous metal material is charged with a solder. The other configurations are the same as those of the first embodiment.

According to the seventh embodiment, the effects of the fourth embodiment and the sixth embodiment can be obtained. More specifically, at the outer region on which relatively high stress acts, the stress can be more effectively relieved as compared with the fourth embodiment.

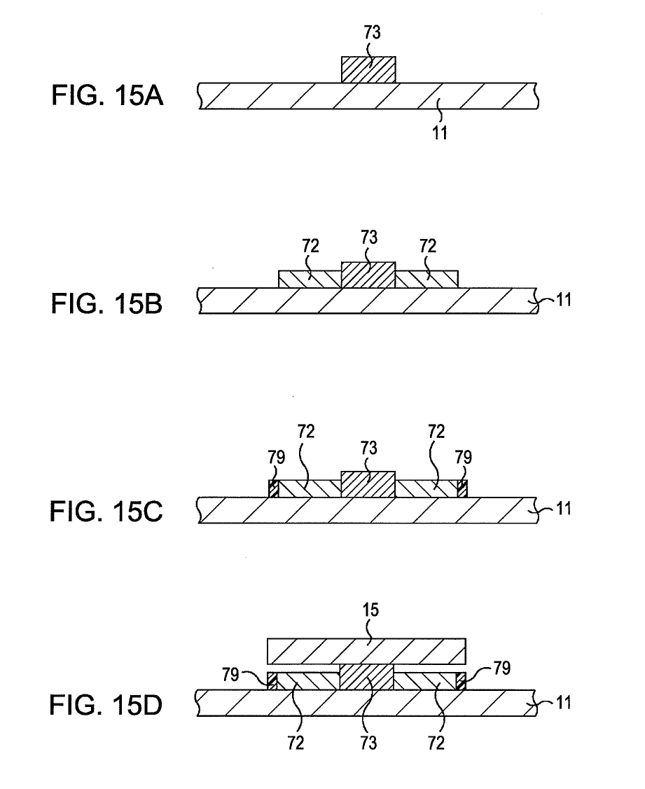

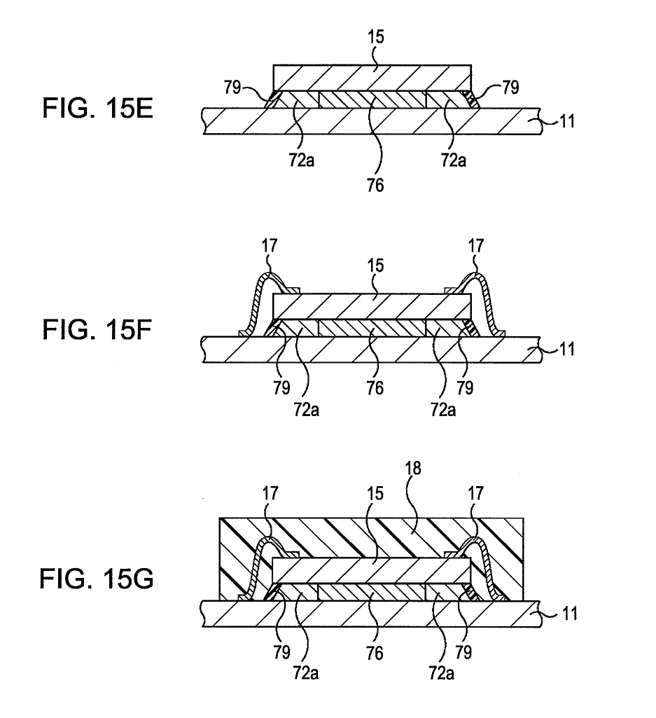

Next, a method for manufacturing the semiconductor device according to the seventh embodiment is described. FIGS. 15A to FIG. 15G are cross sectional views illustrating the method for manufacturing the semiconductor device according to the seventh embodiment in the order of processes.

First, as illustrated in FIG. 15A, a solder sheet 73 is disposed at the central portion of a region of the lead frame 11 where the semiconductor element 15 is to be mounted. As the material of the solder sheet 73, the same one as in the solder sheet 13 may be used. As the solder sheet 73, one smaller than the solder sheet 23 of the second embodiment is used.

Subsequently, as illustrated in FIG. 15B, a nano Ag paste 72 is applied to the circumference of the solder sheet 73 in a region of the lead frame 11 where the semiconductor element 15 is to be mounted. As the nano Ag paste 72, the same one as in the nano Ag pastes 12 and 14 may be used. The nano Ag paste 72 is applied to a wider area than the area of the nano Ag paste 22 of the second embodiment corresponding to the size of the solder sheet 73 which is smaller than the solder sheet 23.

Thereafter, as illustrated in FIG. 15C, a resin material 79 is provided at the circumference of the nano Ag paste 72. As the resin material 79, a resin paste can be used, for example.

Then, as illustrated in FIG. 15D, the semiconductor element 15 is mounted in a face-up manner on the solder sheet 73, the nano Ag paste 72, and the resin material 79.

Subsequently, at least the nano Ag paste 72 and the solder sheet 73 are heated to molt the solder sheet 73. Thereafter, the molten solder is solidified by cooling. In this process, the Ag particles contained in the nano Ag paste 72 are sintered before the solder sheet 73 melts, to thereby form a film- like porous metal material. Then, when the solder sheet 73 melts, the molten solder partially flows into the pores of the porous metal material. In this case, the amount of the solder sheet 73 is small in the seventh embodiment, and therefore, the entire solder flows into the pores of the porous metal material. In contrast, the solder does not flow into the outer region of the porous metal material. When the solder is solidified with the subsequent cooling process, a porous metal material 72a is formed at the outer region and a composite material 76 is formed inside the porous material 72a. The side surfaces of the porous metal material 72a are covered with the resin material 79. More specifically, the resin material 79 remains in a state where the resin material 79 contacts the undersurface of the semiconductor element 15 and the upper surface of the lead frame 11.

Subsequently, as illustrated in FIG. 15F, the terminals of the semiconductor element 15 are connected to the leads of the lead frame 11 by die bonding using the bonding wires 17. Subsequently, as illustrated in FIG. 15G, the semiconductor element 15, the composite material 76, the porous metal material 72a, the resin material 79, and the bonding wires 17 are sealed with the mold resin 18.

Thereafter, a resin-sealed assembly is removed from a die, and then the outer leads of the lead frame 11 are cut to divide the same into semiconductor devices. Thus, a discrete package containing the GaN-based HEMT semiconductor element 15, for example, is obtained.

In all the embodiments, it is preferable to use one containing Sn—Bi-based solder particles and Cu particles as the solder paste. In this case, a layer containing the Cu and the Sn is formed on the surface of the Cu particles in melting the solder paste by heating. Since the melting point of the layer is higher than the melting point (about 240° C.) of the Sn—Bi-based solder, junction strength at higher temperatures can be sufficiently secured.

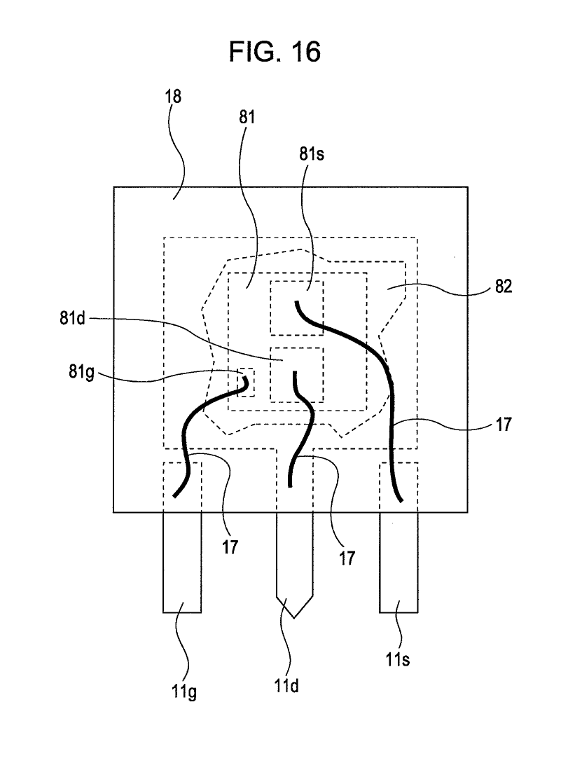

When the semiconductor element is the GaN-based HEMT, the semiconductor devices according to these embodiments can be used as a high power amplifier of a discrete package, for example. FIG. 16 illustrates an example of a discrete package containing the GaN-based HEMT. In this example, an HEMT chip 81 is used as a semiconductor element. The HEMT chip 81 is bonded, through a binder 82, onto the land of a lead frame including a gate lead 11g, a drain lead 11d, and a source lead 11s. A gate terminal 81g of the HEMT chip 81 is connected to the gate lead 11g, a drain terminal 81d is connected to the drain lead 11d, and a source terminal 81s is connected to the source lead 11s, through the bonding wires 17. These components are sealed with the mold resin 18.

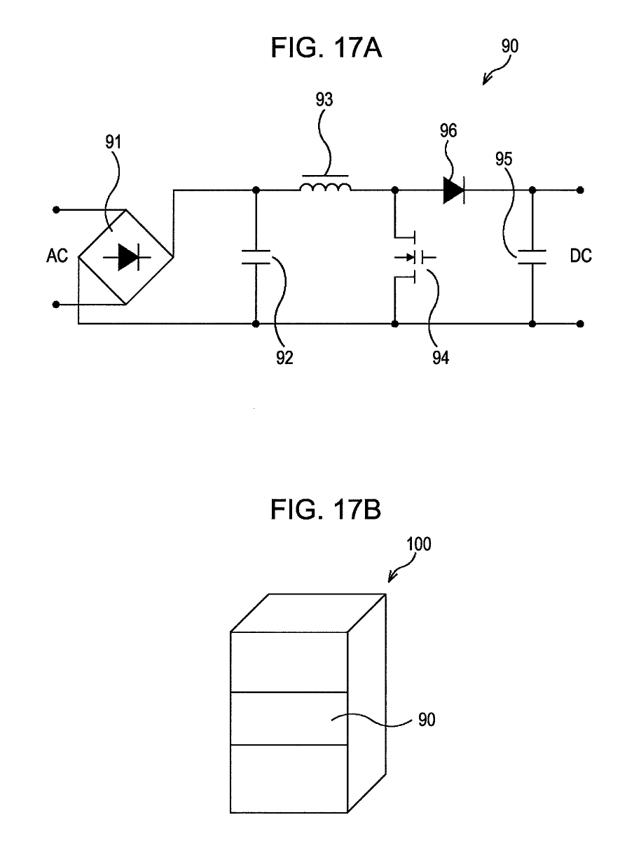

The GaN-based HEMT can also be used for a power supply device, for example. FIG. 17A is a view illustrating a power factor correction (PFC) circuit. FIG. 17B is a view illustrating a server power supply (power supply device) including the PFC circuit illustrated in FIG. 17A.

As illustrated in FIG. 17A, a PFC circuit 90 is provided with a capacitor 92 connected to a diode bridge 91 to which an alternating-current power supply (AC) is to be connected. One terminal of a choke coil 93 is connected to one terminal of the capacitor 92 and one terminal of a switch element 94 and an anode of a diode 96 are connected to the other terminal of the choke coil 93. The switch element 94 is equivalent to the semiconductor element (HEMT) in the above-described embodiments, and the one terminal thereof is equivalent to the drain electrode of the HEMT. The other terminal of the switch element 94 is equivalent to the source electrode of the HEMT. One terminal of a capacitor 95 is connected to the cathode of the diode 96. The other terminal of the capacitor 92, the other terminal of the switch element 94, and the other terminal of the capacitor 95 are grounded. Then, a direct-current power supply (DC) is extracted between both the terminals of the capacitor 95. A gate driver is connected to the gate lead of the switch element 94 (HEMT).

As illustrated in FIG. 17B, the PFC circuit 90 is installed in a server power supply 100 or the like for use.

A power supply device which is similar to such a server power supply 100 and which allows higher speed operation can also be built. A switch element similar to the switch element 94 can be used for a switch power supply or an electronic device. Furthermore, these semiconductor devices can also be used as parts for a full bridge power circuit, such as a power circuit of a server.

The present inventors manufactured a discrete-packaged semiconductor device containing the GaN-based HEMT according to the second embodiment, and then measured the heat resistance of the entire package during the operation of the semiconductor element. Thus, the heat resistance was 0.5° C./W or lower. When a temperature cycle test (3000 cycles) was performed between −65° C. and +150° C., the rate of change in the heat resistance was +5% or lower. Furthermore, a cross-sectional SEM analysis of the junction portion of the semiconductor element and the lead frame was performed after the respective tests. Then, cracks or fractured portions were not observed at the junction portion, and it was confirmed that the early junction state was favorably maintained. When manufacturing the semiconductor device, one containing SnBi solder particles and Cu particles was used as the solder paste.

For comparison, the present inventors manufactured a discrete-packaged semiconductor device containing the GaN-based HEMT according to the second embodiment, except bonding the semiconductor element to the lead frame only using a SnBi solder paste without using the nano Ag paste. Then, the same tests as above were performed. As a result, the heat resistance of 0.7° C./W was 1.4 times or more comparing that in the above results. The rate of change in the heat resistance accompanied with the temperature cycle test was about 10 times comparing with that in the above results. Furthermore, when a cross-sectional SEM analysis of the junction portion was performed, cracks were observed at the junction portion near the outer region of the semiconductor element.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a support base material; and
a semiconductor element bonded to the support base material with a binder, the binder including:
a porous metal material that contacts the support base material and the semiconductor element; and
a solder that is filled in at least one part of pores of the porous metal material.

2. The semiconductor device according to claim 1, wherein the melting point of the porous metal material is higher than the melting point of the solder.

3. The semiconductor device according to claim 1, wherein the porous metal material contains at least one selected from the group consisting of Ag, Au, Ni, Cu, Pt, Pd, and Sn.

4. The semiconductor device according to claim 1, wherein the solder contains at least one selected from the group consisting of Sn, Ni, Cu, Zn, Al, Bi, Ag, In, Sb, Ga, Au, Si, Ge, Co, W, Ta, Ti, Pt, Mg, Mn, Mo, Cr, and P.

5. The semiconductor device according to claim 1, wherein
the porous metal material contacts a metal film a metal film formed on a surface side of the support base material of the semiconductor element

6. The semiconductor device according to claim 5, wherein the metal film contains at least one selected from the group consisting of Ni, Cu, Zn, Al, Ag, Au, W, Ti, Pt, and Cr.

7. The semiconductor device according to claim 1, further comprising a resin material provided in the circumference of the binder that contacts the support base material and the semiconductor element.

8. The semiconductor device according to claim 1, wherein the semiconductor element is a GaN-based transistor.

9. The semiconductor device according to claim 1, wherein the solder ratio becomes continuously or gradually low in plane view from the center of the semiconductor element to the outer region thereof.

10. The semiconductor device according to claim 1, wherein the solder contains Cu particles.

11. The semiconductor device according to claim 1, wherein the plane shape of the porous metal material is annular; and the binder has a solder layer located inside the porous metal material.

12. A power supply device comprising:
a semiconductor device, wherein the semiconductor device comprising:
a support base material; and
a semiconductor element bonded to the support base material with a binder, the binder including:
a porous metal material that contacts the support base material and the semiconductor element; and
a solder that is filled in at least one part of pores of the porous metal material.

13. A method for manufacturing a semiconductor device, the method comprising:
forming a paste containing metal particles and a solder on a support base material;
mounting a semiconductor element on the paste containing metal particles and the solder;
sintering the metal particles by heating to form a porous metal material in contact with the support base material and the semiconductor element, and melting the solder to make at least one part of the molten solder flow into pores of the porous metal material; and
solidifying the solder by cooling.

14. The method according to claim 13, wherein the melting point of the solder is higher than a temperature at which the metal particles are sintered and lower than the melting point of the metal particles.

15. The method according to claim 13, wherein the metal particles contain at least one selected from the group consisting of Ag, Au, Ni, Cu, Pt, Pd, and Sn.

16. The method according to claim 13, wherein the solder contains at least one selected from the group consisting of Sn, Ni, Cu, Zn, Al, Bi, Ag, In Sb, Ga, Au, Si, Ge, Co, W, Ta, Ti, Pt, Mg, Mn, Mo, Cr, and P.

17. The method according to claim 13, wherein the porous metal material contacts a metal film that is formed on a surface side of the support base material of the semiconductor element.

18. The method according to claim 13, comprising:
forming a resin material in contact with the support base material and the semiconductor device in the circumference of the porous metal material.

19. The method according to claim 13, wherein the semiconductor element is a GaN-based transistor.
